(19) United States
(12) Patent Application Publication
(10) Pub. No.: US 2012/0320003 A1
(43) Pub. Date: Dec. 20, 2012

(54) COF, COF CARRIER TAPE AND DRIVE CIRCUIT OF LIQUID CRYSTAL TELEVISION

(75) Inventors: Liang-chan Liao, Shenzhen (CN); Po-shen Lin, Shenzhen (CN); Yong Zhang, Shenzhen (CN)

(73) Assignee: SHENZHEN CHINA STAR OPTOELECTRONICS TECHNOLOGY CO., LTD., Shenzhen (CN)

(21) Appl. No.: 13/377,981

(22) PCT Filed: Jul. 26, 2011
(86) PCT No.: PCT/CN2011/077597

§ 371 Date: Dec. 13, 2011

(30) Foreign Application Priority Data
Jun. 17, 2011 (CN) 201110164398.9

(51) Int. Cl. G09G 5/00; H01L 23/498

(52) U.S. Cl. 345/204; 257/774; 257/E23.067

(57) ABSTRACT

The present disclosure discloses a COF (Chip On Film), the plane shape of which is a non-orthogonal parallelogram. The present disclosure further discloses a COF carrier tape, which includes a COF tape formed by orderly connecting several COF and a carrier connected with said COF tape. The plane shape of said COF is a non-orthogonal parallelogram. Said COF includes two paralleled wiring edges, and the two adjacent wiring edges of said COF are mutually connected. The present disclosure also discloses a drive circuit for liquid crystal display television. With the COF wiring number increased, the wiring intervals of the present disclosure remain unchanged. When the wiring number of COF are no longer increased, the lengths of the wiring edges can be shortened if the intervals remain unchanged; as a result, the total area of COF can reduced so that the cost can be effectively lowered.

### BACKGROUND

1. Technical Field

The present disclosure relates to a COF (Chip On Film), specifically to a COF, COF carrier tape and a drive circuit of liquid crystal television.

2. Description of Related Art

COF carrier tape joints the semiconductor elements and then installs them on the long carrier tape. COF uses a soft additional circuit board as the packaged chip carrier in order to joint the chip and the soft substrate circuits; or COF only refers to the soft additional circuit board of the unpackaged chip. As is shown in FIG. 1, COF is formed by jointing the chip (such as source driver IC or gate driver IC, etc. see the black-coloured shadow part in FIG. 1) and installing the chip on a flexible wiring substrate on which the wiring diagrams are formed. The wiring diagrams of COF are generally composed of an internal lead connected with the chip electrode and an external lead connected with the external circuit. Generally, in the driver circuit of the liquid crystal display television, the wiring on one end of COF connected to the PCB (Printed Circuit Board) is sparse, while the wiring on the other end connected to the panel is dense.

The material cost of COF is closely associated with its area. When the area of COF increases, the cost will also increases relatively. Since the wiring from the COF to the panel is denser, which is not beneficial for transmitting signals; thus the working performance of the products will be influenced. As is shown in FIG. 2, the length a of the side of COF cannot be changed randomly under generation situation; when the wiring number of the wiring edge b increases, the wiring edge b should be lengthened in order not to reduce the space between the wirings and not to reduce the transmission speed of the signal; thereby, the area of COF will increase and its manufacturing cost will increase as well.

### SUMMARY

The main purpose of the present disclosure is to provide a COF, a COF carrier tape and a drive circuit of the liquid crystal display television and the aim of the present disclosure is to realize that the signal transmission speed would not be reduced and the COF area is not necessarily enlarged when the COF wiring number increases; or when the COF wiring number does not increase, and the wiring space of COF would not change; thereby, the area of COF can be reduced and the cost can be lowered effectively.

The present disclosure discloses a COF with a plane shape thereof being a non-orthogonal parallelogram.

Preferably, said COF includes a strip-shaped driver IC parallel with the wiring edges of said COF.

Preferably, said COF includes a strip-shaped driver IC unparallel with the wiring edges of said COF.

Preferably, one of said COF wiring edges is provided with a plurality of connecting wires capable of being connected with the external PCB, and the other wiring edge is provided with a plurality of connecting wires capable of being connected with the external panel.

The present disclosure further discloses a COF carrier tape, including a COF tape formed by orderly connecting several COFs and a carrier connected with said COF tape. The plane shape of said COF is a non-orthogonal parallelogram. Said COF includes two paralleled wiring edges, and the two adjacent wiring edges of said COF are mutually connected.

Preferably, said carrier includes two paralleled long sides; the two side edges of said COF are all in parallel with said long sides. The included angle formed respectively between the two wiring edges of said COF and said long sides is non-orthogonal.

Preferably, each said COF has same size and same area.

Preferably, a plurality of through holes are defined at two edges of the long side of the carrier respectively, and each of the two side edges of the COF correspond to one to six of the through holes.

Preferably, said COF comprises a strip-shaped driver IC; and said strip-shaped driver IC is vertical to the long side of said carrier tape.

Preferably, one of the wiring edges of said COF is provided with a plurality of connecting wires capable of being connected with an external PCB, and the other wiring edge is provided with a plurality of connecting wires capable of being connected with an external panel.

The present disclosure further discloses a drive circuit for the liquid crystal display television, including a COF. One of the wiring edges of said COF is connected to a PCB and the other one of the wiring edges is connected to an external panel; and a plane shape of said COF is a non-orthogonal parallelogram.

Preferably, said COF includes a strip-shaped driver IC parallel with the wiring edges of said COF.

Preferably, said COF comprises a strip-shaped driver IC unparallel with the wiring edges of said COF.

The COF of the present disclosure is a quadrilateral structure consisting of two sides which are opposite paralleled sides and two opposite sides as the wiring edges; the four angles of the COF are non-orthogonal. The COF of the present disclosure is, for instance, a parallelogram structure, while the existing COF is a rectangular structure. On the premise of not changing the area of the COF, the shape is converted into a parallelogram; as a result, the two wiring edges are lengthened. When the wiring number of the COF increases, the wiring space remains unchanged so that the signal transmission speed cannot be reduced; when the wiring number of the COF do not increases, the existing COF with rectangular structure is converted into parallelogram, and then the wiring space of the COF will increases. If the space needs to be unchanged, the length of the wiring edge can be shortened and then the total area of the COF is reduced. Moreover, the cost can be effectively reduced with this method.

### DESCRIPTION OF THE DRAWINGS

FIG. 1 is the schematic diagram showing the structure of the existing COF connected with the external;

FIG. 2 is the schematic diagram showing the structure of the existing COF carrier tape;

FIG. 3 is the schematic diagram showing the structure of the COF in the first embodiment according to the present disclosure;

FIG. 4 is the schematic diagram showing the structure of the COF carrier tape in the first embodiment according to the present disclosure;

FIG. 5 is the schematic diagram showing the structure of the COF in the second embodiment according to the present disclosure;

FIG. 6 is the schematic diagram showing the structure of the COF carrier tape in the second embodiment according to the present disclosure;

FIG. 7 is the schematic diagram showing the structure of the COF in the third embodiment according to the present disclosure.

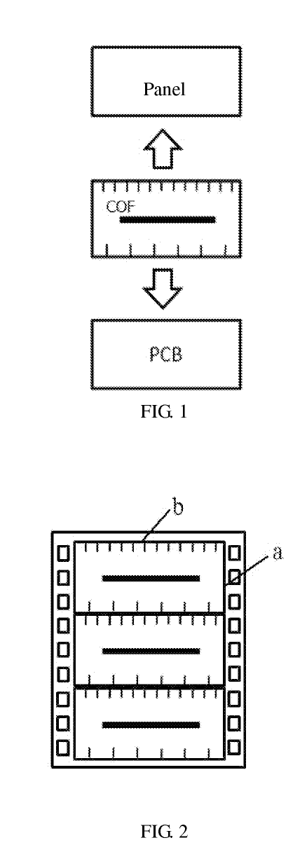

The purpose implementation, the function features and advantages of the present disclosure will be further illustrated by integrating the exemplary embodiments and taking the attached drawings as references.

### DETAILED DESCRIPTION

It should be understood that the described exemplary embodiment is only used for illustrating this present disclosure rather than limiting.

Take FIG. 3 as a reference, which is the schematic diagram showing the structure of the COF in a first embodiment according to the present disclosure. Such COF 100 is a quadrilateral structure consisting of two side edges 101 which are opposite paralleled sides and two opposite sides 102 as the wiring edges. The four angles of the COF 100 are non-orthogonal. The appearance of COF 100 in this embodiment is a parallelogram structure. One wiring edge 102 of the COF 100 is provided with a plurality of connecting wires capable of being connected with the external PCB, and the other paralleled wiring edge is provided with a plurality of connecting wires capable of being connected with the external panel. COF 100 includes a strip-shaped driver IC 103, and said strip-shaped driver IC103 can be arranged in any position on the COF 100. Said strip-shaped driver IC 103 is in parallel with the wiring edge of COF, or such strip-shaped driver IC 103 is in unparallel with the wiring edge of COF.

All the four angles of COF 100 of the present disclosure are non-orthogonal. However, the existing COF is a rectangular structure. In the present disclosure, assumes x′ as the length of the wiring edge 102 of COF 100 and assumes x as the projected horizontal length of x′, x is equal to the wiring edge length of the existing COF. Under the condition of remaining the plane area of COF 100 unchangeable and the distance between the two side edges 101 of COF 100 also unchangeable, the included angle between two adjacent side edges with the COF100 is θ (θ is less than 90 degrees) after deforming the existing COF into the parallelogram-shaped COF100 of the present disclosure. The side length of the wiring edge 102 of COF 100 x′=x/sinθ in the present disclosure; when sinθ is less than 1, then side lengths of the two wiring edges 102 of the parallelogram are lengthened and x′ is larger than x; when the wiring number of COF 100 increases, the wiring space remains unchangeable. The wiring space is very important for the integrity of the high-speed signals. After the side lengths x′ of the two wiring edges 102 are lengthened and when the wiring number of COF 100 does not increase, the wiring space of COF100 will increase which is more beneficial for transmitting high-speed signals and improving the working performance of the products. The wiring number of COF 100 does not increase. And if the space needs to be unchanged, the length of the short wiring edge 102 can be shortened in order to make the x′ be shortened to x; at this moment, the total area of COF 100 can be reduced; besides, the cost can be effectively reduced with this method.

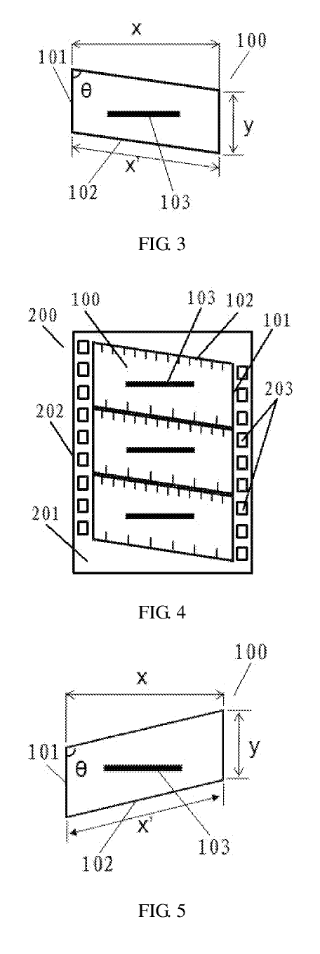

Take FIG. 4 as a reference, which is the schematic diagram showing the structure of the COF carrier tape in a first embodiment according to the present disclosure. Such COF carrier tape 200 includes a COF tape formed by orderly connecting several COF 100 and a carrier 201 connected with said COF tape. The COF 100 is a quadrilateral structure consisting of two sides 101 which are opposite paralleled sides and two opposite sides as the wiring edges 102. The two adjacent wiring edges 102 of COF 100 are mutually connected. All the four angles of COF 100 are non-orthogonal. The included angle between the two wiring edges 102 of COF 100 and the long sides 202 respectively is non-orthogonal. The COF100 in this embodiment is a parallelogram structure. Said carrier 201 includes two mutually-paralleled long sides 202. The two side edges 101 of COF 100 are all in parallel with the long sides 202, and the two side edges 101 of COF 100 are close to the edge of the carrier 201; moreover, the shape and the area of each COF 100 are same. A plurality of through holes 203 are arranged on the edge of the long side 202 of the carrier 201. The two sides 101 of COF 100 are respectively corresponded to 1-6 through hole 203; and said through hole 203 is used for connecting the COF carrier tape 200 with the external cutting equipments conveniently and guaranteeing each COF 100 to be cut integrally. The side edges 101 of COF 100 are respectively corresponded to three through holes 203, respectively. COF 100 includes a strip-shaped IC 103. The strip-shaped IC 103 of this embodiment is vertical to the long side 202 of the carrier tape.

The COF carrier tape 200 of the present disclosure is composed of a plurality of COF 100 with parallelogram-structured appearances and carriers 201 with through holes 203. The COF carrier tape 200 incises the orderly-connected COF 100 through an equipment; although the total area of COF 100 is not changed, the length of each wiring edge 102 is lengthened. When the wiring numbers of COF 100 do not increase, the wiring space of COF 100 will increase which is beneficial for transmitting the high-speed signals and improving the product yield. When the wiring numbers do not increase, the length of the wiring edge 102 can be shortened if the space should be unchangeable; at this moment, the total area of the COF 100 can be reduced and the cost can be lowered effectively.

Take FIG. 5 as a reference, which is the schematic diagram showing the structure of the COF in a second embodiment according to the present disclosure. The difference between this embodiment and the first embodiment is that the included angle θ between the two adjacent sides in COF 100 is changed from less than 90 degrees to larger than 90 degrees, however, the technical effect is same. The structure of this embodiment can be adopted according to the requirement in practical application.

Take FIG. 6, which is the schematic diagram showing the structure of the COF carrier tape 200 in the second embodiment according to the present disclosure. The difference between the COF carrier tape 200 in the second embodiment and that in the first embodiment lies in that the COF carrier tape 200 uses the structure of COF 100 in the second embodiment.

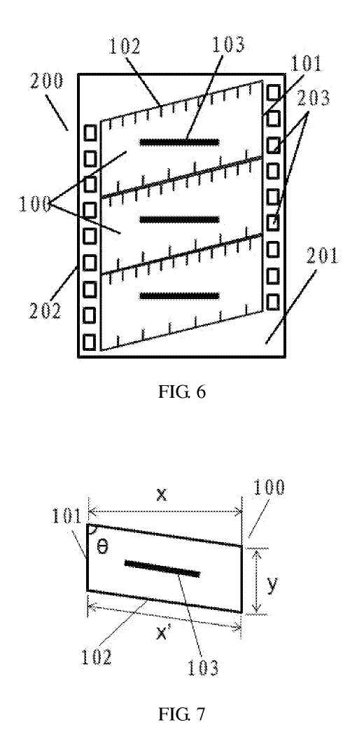

Take FIG. 7 as a reference, which is the schematic diagram showing the structure of the COF in a third embodiment according to the present disclosure. The difference between the COF 100 in the third embodiment and the COF 100 in the first embodiment lies in that the position of the strip-shaped driver IC 103 is changed; the strip-shaped driver IC 103 is in parallel with the wiring edge 102 of the COF 100, which does not exert any influence and change for the using function of COF 100. The structure of this embodiment can be used according to the requirement in practical application. The application principle of the COF carrier tape 200 in the third embodiment is as same as that of the COF carrier tape 200 in the first embodiment, so it would not be illustrated in details here.

The method for manufacturing COF carrier tape 200 lies as follows. COF 100 is designed as a non-orthogonal quadrangle when it is designed on the carrier 201; if it is designed as a parallelogram, then the wiring edges 102 of the COF 100 are all obliquely arranged. According to the practical requirement, the oblique angle is determined by the wiring numbers and wiring space on the wiring edges so as to control the length of the wiring edge 102.

The present disclosure further discloses a drive circuit of the liquid crystal display television, including a COF 100 (see FIG. 3, FIG. 5 and FIG. 7 as references). One of the wiring edges of COF 100 is connected with PCB, and the other wiring edge is connected with the external panel. The plane shape of COF 100 is a non-orthogonal parallelogram.

COF 100 includes a strip-shaped IC 103, and the strip-shaped IC 103 is in parallel with the wiring edge of COF 100. Or, such strip-shaped IC 103 is in unparallel with the wiring edge of COF 100. The COF 100 of the drive circuit of the liquid crystal display in this embodiment includes all the technical methods in the first embodiment, the second embodiment and the third embodiment; meanwhile, the reached technical effects are same, thus details would not be illustrated here.

What is illustrated above is just a preferable exemplary embodiment, which will not limit the patent scope of the invention. Any equivalent replacements made by the specifications and drawings of the invention, which are directly or indirectly applied to other technical fields, should be included into the protection scope of the invention.

What is claimed is:

1. A COF, wherein the plane shape of said COF is a non-orthogonal parallelogram.

2. The COF of claim 1, wherein said COF comprises a strip-shaped driver IC parallel with the wiring edge of said COF.

3. The COF of claim 1, wherein said COF comprises a strip-shaped driver IC unparallel with the wiring edge of said COF.

4. The COF of claim 2, wherein one of said COF wiring edges is provided with a plurality of connecting wires capable of being connected with an external PCB, and the other wiring edge is provided with a plurality of connecting wires capable of being connected with an external panel.

5. A COF carrier tape, wherein the COF carrier tape comprises a COF tape formed by orderly connecting several COFs and a carrier connected with said COF tape; the plane shape of said COF is a non-orthogonal parallelogram; said COF comprises two paralleled wiring edges, and the two adjacent wiring edges of said COF are mutually connected.

6. The COF carrier tape of claim 5, wherein said carrier comprises two paralleled long sides;
the two side edges of said COF are all in parallel with said long sides; the included angle formed respectively between the two wiring edges of said COF and said long sides is non-orthogonal.

7. The COF carrier tape of claim 5, wherein each said COF has same size and same area.

8. The COF carrier tape of claim 6, characterized in that, each said COF has same size and same area.

9. The COF carrier tape of the claim 8, wherein a plurality of through holes are defined at two edges of the long side of the carrier respectively, and each of the two side edges of the COF correspond to one to six of the trough holes.

10. The COF carrier tape of claim 9, wherein said COF comprises a strip-shaped driver IC;
and said strip-shaped driver IC is vertical to the long side of said carrier tape.

11. The COF carrier tape of claim 9, wherein one of the wiring edges of the COF is provided with a plurality of connecting wires capable of being connected to an external PCB, and the other one of the wiring edges of COF is provided with a plurality of a plurality of connecting wires capable of being connected to an external panel.

12. A drive circuit for a liquid crystal display television comprising a COF, wherein the COF comprises two wiring edges, one of the wiring edges is connected to a PCB, the other one of the wiring edges is connected to an external panel, and a plane shape of the COF is a non-orthogonal parallelogram.

13. The drive circuit as claimed in claim 12, wherein the COF comprises a strip-shaped driving IC parallel with the wiring edges of the COF.

14. The drive circuit as claimed in claim 12, wherein the COF comprises a strip-shaped driving IC unparallel with the wiring edges of the COF.
